(19) United States
(12) Patent Application Publication
(10) Pub. No.: US 2026/0172038 A1
(43) Pub. Date: Jun. 18, 2026

(54) FRACTIONAL DIVIDER CALIBRATION WITH DUAL DIGITAL CONTROL DELAY CIRCUITS

(71) Applicant: Renesas Electronics America Inc., Milpitas, CA (US)

(72) Inventor: Chengming HE, Chandler, AZ (US)

(73) Assignee: Renesas Electronics America Inc., Milpitas, CA (US)

(21) Appl. No.: 18/980,599

(22) Filed: Dec. 13, 2024

(51) Int. Cl. H03L 7/197; H03K 23/68; H03L 7/08

(52) U.S. Cl. CPC H03L 7/1974; H03L 7/08; H03K 23/68

(57) ABSTRACT

Systems and methods for calibrating a fractional divider are described. A system can include a divider and a circuit. The divider can divide an input clock signal to generate an integer output divider (IOD) signal. The circuit can include a first digital control delay (DCD) circuit configured to delay the IOD signal to generate a first delayed IOD signal. The circuit can further include a second DCD circuit configured to delay the first delayed IOD signal to generate a second delayed IOD signal. The circuit can further include an edge sampler configured to compare an edge of the second delayed IOD signal with an edge of the input clock signal. The circuit can further include a controller configured to calibrate the first DCD circuit based on a result of the comparison between the edge of the second delayed IOD signal with the edge of the input clock signal.

### BACKGROUND

The present disclosure relates in general to semiconductor devices. More specifically, the present disclosure relates to clock generation systems that utilizes fractional dividers with calibration using dual digital control delay circuits.

Clock generation systems can utilize phase-locked loops (PLLs) to generate stable, accurate, and adjustable clock signals for different components in a digital system. The PLL can include a divider to divide a clock signal into different clock signals. An integer divider can divide a clock signal by an integer and a fractional divider can divide the clock signal by a non-integer. Fractional-N PLLs can utilize a fractional divider to divide an input clock signal.

### SUMMARY

In one embodiment, a semiconductor device for fractional divider calibration is generally described. The semiconductor device can include a first digital control delay (DCD) circuit configured to delay an integer output divider (IOD) signal to generate a first delayed IOD signal. The semiconductor device can include a second DCD circuit configured to delay the first delayed IOD signal to generate a second delayed IOD signal. The semiconductor device can include an edge sampler configured to sample an edge of the second delayed IOD signal. The semiconductor device can include a controller configured to calibrate the first DCD circuit based on the edge sampled from the second delayed IOD signal.

In one embodiment, a system implementing a fractional divider is generally described. The system can include a divider and a circuit. The divider can be configured to divide an input clock signal to generate an integer output divider (IOD) signal. The circuit an include a first digital control delay (DCD) circuit configured to delay the IOD signal to generate a first delayed IOD signal. The circuit can further include a second DCD circuit configured to delay the first delayed IOD signal to generate a second delayed IOD signal. The circuit can further include an edge sampler configured to compare an edge of the second delayed IOD signal with an edge of the input clock signal. The circuit can further include a controller configured to calibrate the first DCD circuit based on a result of the comparison between the edge of the second delayed IOD signal with the edge of the input clock signal.

In one embodiment, a method for calibrating a fractional divider is generally described. The method can include dividing an input clock signal to generate an integer output divider (IOD) signal. The method can further include delaying the IOD signal to generate a first delayed IOD signal. The method can further include delaying the first delayed IOD signal to generate a second delayed IOD signal. The method can further include comparing an edge of the second delayed IOD signal with an edge of the input clock signal. The method can further include calibrating a digital control delay (DCD) circuit that generated the first delayed IOD signal. The calibration can be based on a result of the comparison between the edge of the second delayed IOD signal with the edge of the input clock signal.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 is a diagram showing an example system that can implement fractional divider calibration with dual digital control delay circuits in one embodiment.

FIG. 2 is a diagram showing an example implementation of fractional divider calibration with dual digital control delay circuits in one embodiment.

FIG. 3 is a diagram showing an example implementation of a digital control delay (DCD) circuit in one embodiment.

FIG. 4 is a diagram showing an example calibration process in one embodiment.

FIG. 5 is a flowchart of an example process that can implement fractional divider calibration with dual digital control delay circuits in one embodiment.

### DETAILED DESCRIPTION

In the following description, numerous specific details are set forth, such as particular structures, components, materials, dimensions, processing steps and techniques, to provide an understanding of the various embodiments of the present application. However, it will be appreciated by one of ordinary skill in the art that the various embodiments of the present application may be practiced without these specific details. In other instances, various structures or processing steps have not been described in detail to avoid obscuring the present application.

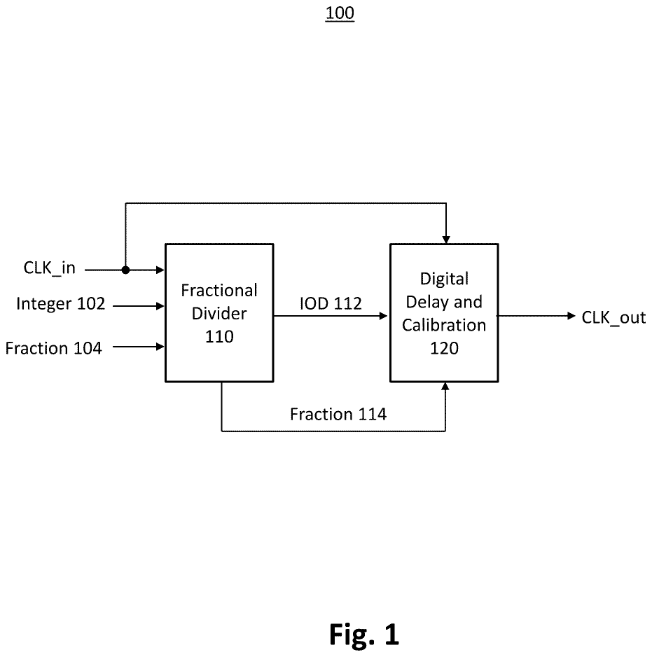

FIG. 1 is a diagram showing an example system that can implement fractional divider calibration with dual digital control delay circuits in one embodiment. FIG. 1 is a diagram showing an example system that can implement fractional divider calibration with dual digital control delay in one embodiment. System 100 shown in FIG. 1 can be implemented as a fractional divider with a calibrated digital control delay circuit to provide jitter reduction. System 100 can include at least a fractional divider 110 and a digital delay and calibration circuit 120 (hereinafter “circuit 120”). Fractional divider 110 and digital delay and calibration circuit 120 can be implemented by one or more semiconductor devices. Fractional divider 110 can be a circuit including various input and output pins or interfaces. Fractional divider 110 can receive an input clock signal CLK_in, an integer 102 and a fraction 104 at a plurality of input pins. Input clock signal CLK_in can be an output of a voltage-controlled oscillator (VCO) in a clock generation system. In one embodiment, integer 102 can be a digital code, such as a 4-bit digital signal, encoding an integer value. Fractional divider 110 can convert the input clock signal CLK_in into an integer output divider (IOD) signal 112 (hereinafter “IOD 112”). IOD 112 can be a divided clock signal resulting from dividing the input clock signal CLK_in by a value that is a combination of integer 102 and fraction 104. Fractional divider 110 can output IOD 112 and forward fraction 104 from its output pins to circuit 120.

Circuit 120 can be configured to reduce jitter from IOD 112 by delaying or advancing individual clock pulses in IOD 112. An output from circuit 120, labeled as the output clock signal CLK_out, can be the signal IOD 112 with jitter reduced or removed. Circuit 120 can be configured to determine an amount of delay to be added to, or to be removed from, the IOD 112 to generate output clock signal CLK_out. Circuit 120 can be further configured to calibrate the circuitry being used for determining the delay for generating output clock signal CLK_out.

Conventionally, a fractional output divider (FOD), such as fractional divider 110, without jitter reduction can divide an input clock signal by a fractional divisor (e.g., not an integer) to generate an output clock signal. FODs can be implemented by using an integer divider to alternately divide the input clock signal between dividing by N and N+1. For example, to divide the input clock signal by 2.25, the integer divider can divide the input clock signal by 2 (e.g., N=2) for the first three clock periods and by 3 (e.g., N+1=3) for the fourth or last clock period. However, this alternating division can introduce jitter at the FOD's output since some of the rising edges and falling edges of the output clock signal (e.g., the result of the division) appear at irregular times.

To reduce jitter, in addition to alternating between two divisors, variable delays are added to ensure that the output clock signal has a period that is equal to the period of the input clock signal divided by the fractional divisor. These delays are controlled by a digital control delay (DCD) circuit. The DCD circuit can control the delays through variable capacitance, variable current or variable resistance, to change the charge/discharge constant of a programmable capacitor array, thus delaying (e.g., delaying falling edge) or advancing (e.g., bring rising edge earlier) by a varying degree the corresponding edge. However, it is challenging to ensure that the DCD circuit will generate the correct delay, since the selectable capacitance, current or resistance can be affected by changes in process, variation, temperature (PVT). Non-idealities in the DCD caused by PVT variations can create jitter or spurs in the output clock signal.

To calibrate the DCD circuit, some conventional techniques can set the DCD circuit to work in self-oscillation, or in other words, as a ring oscillator. In that case, a number of given edges (either rising or falling) of the output of the ring oscillator are averaged over a long-enough period of time, and compared with the expected value (e.g., expected timing), until the DCD circuit is correctly calibrated. However, the switch from the ring oscillator topology to the open-loop oscillation (e.g., normal operation of the clock generation system) can introduce various errors. Calibration of the DCD circuit for self-oscillation does not guarantee that the DCD circuit will be calibrated for open-loop topologies. Also, the errors becomes non-negligible for modern high-speed links. For example, delay in the ring oscillation mode can be 5-10 picoseconds (ps) off from open-loop delay mode when configured for 100 ps delay, which is a significant error (e.g., 5% to 10% error).

In the present disclosure, circuit 120 can include two DCD circuits—a first DCD circuit configured to be an output DCD circuit for determining delays to be applied (e.g., add or subtract) on IOD 112, and a second DCD circuit configured to calibrate the first DCD circuit. The second DCD circuit in circuit 120 can in different delay modes during a calibration process to calibrating the first DCD circuit. By using the dual DCD circuit topology in circuit 120 to continuously calibrate the output DCD circuit, the delay being applied by the output DCD circuit can be more accurate since the delay can vary according to instantaneous PVT variations.

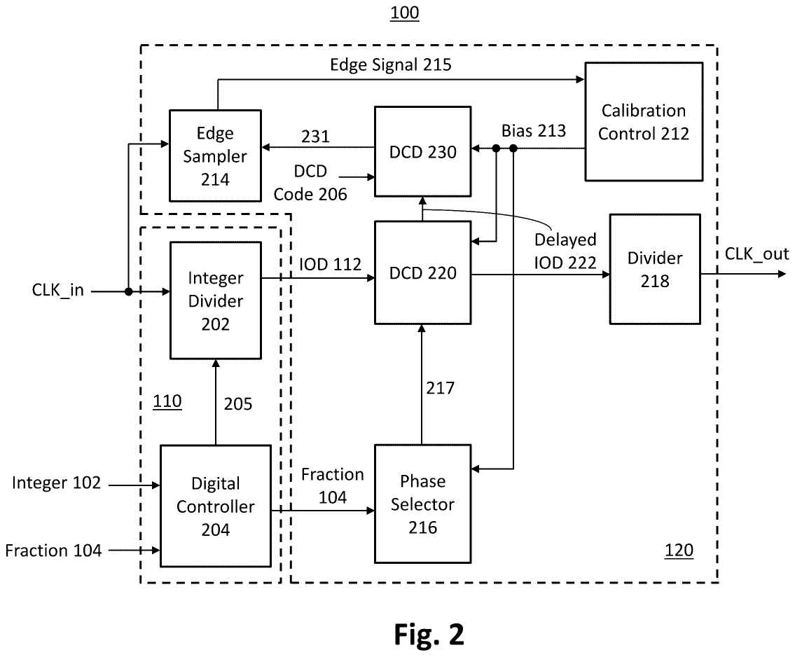

FIG. 2 is a diagram showing an example implementation of fractional divider calibration with dual digital control delay circuits in one embodiment. Descriptions of FIG. 2 can reference components shown in FIG. 1. Fractional divider 110 can include an integer divider 202 and a digital controller 204. Integer divider 202 can be a circuit, such as a multi-modulus divider (MMD), configured to receive the input clock signal CLK_in and divide the input clock signal CLK_in by one or more integers. Digital controller 204 can be, for example, a microcontroller including various hardware and electronic components, such as processors, logic circuits, analog to digital converters (ADCs), digital to analog converters (DACs), comparators, mixers, amplifiers, and various electronic components.

Digital controller 204 can receive integer 102 and fraction 104. Digital controller 204 can send a control signal 205 at each clock cycle to control the division being performed by integer divider 202. For example, if integer 102 is 2 and the fraction 104 is 0.25 or ¼, then digital controller 204 can determine that integer divider 202 needs to divide input clock signal CLK_in by 2.25. In the first three cycles, digital controller 204 can encode the number 2 in control signal 205 and send control signal 205 to integer divider 202 to divide input clock signal CLK_in by 2 for three clock cycles. Then, digital controller 204 can, in the fourth clock cycle, encode the number 3 in control signal 205 and send control signal 205 to integer divider 202 to divide input clock signal CLK_in by 3. In one embodiment the control signal 205 can be a digital code, such as a 4-bit or 8-bit digital signal, encoding the integer for integer divider 202 to perform the division. Digital controller 204 can perform various other signal processing techniques, such as noise filtering, synchronization, frequency adjustment on the output of fractional divider 110 (e.g., IOD 112), and other signal processing techniques.

Circuit 120 can include a calibration control circuit 212 (hereinafter “circuit 212”), an edge sampler 214, a phase selector 216, a divider 218, a DCD circuit 220 and a DCD circuit 230. Circuit 212 can be a controller, such as a microcontroller including various hardware and electronic components, such as processors, logic circuits, analog to digital converters (ADCs), digital to analog converters (DACs), comparators, mixers, amplifiers, and various electronic components.

Edge sampler 214 can be a circuit configured to receive one or more signals and detect or sample the edges, such as rising and/or falling edges, of the received signals. Edge sampler 214 can also compare sampled edges between different signals and generate an edge signal 215 indicating results of the comparison. Edge sampler 214 can send edge signal 215 to circuit 212. In the calibration process described in the present disclosure, circuit 212 can use edge signal 215 to generate a bias 213. Bias 213 can be used for tuning variable current sources in DCD circuits 220, 230. Bias 213 can be a bias current for adjusting current sources in DCD circuits 220, 230.

Phase selector 216 can be a circuit, such as a phase accumulator, configured to generate a signal 217. Signal 217 can be a digital code, such as a DCD code that can tune a capacitive characteristic of DCD circuit 220 to adjust delays being applied to IOD 112 in the generation of a delayed IOD 222. During the calibration process described in the present disclosure, phase selector 216 can generate signal 217 to tune the capacitance of output DCD circuit 220 until a desired condition is achieved. During normal operations without calibration, phase selector 216 can convert fraction 104 into a signal 217 to tune certain components (such as capacitance) of output DCD circuit 220 to delay IOD 112 according to fraction 104. Also, during calibration, circuit 212 and phase selector 216 can communicate with each other to determine tuning parameters for tuning output DCD circuit 220 and calibration circuit 230.

DCD circuit 220 can be configured as an output DCD circuit and DCD circuit 230 can be configured as a calibration DCD circuit. DCD circuit 220 can receive IOD 112 from integer divider 202 and receive signal 217 from phase selector 216. DCD circuit 220 can be tuned by the signal 217 to apply a delay on IOD 112 to generate delayed IOD 222. The delayed IOD 222 can be IOD 112 with reduced jitter. DCD circuit 220 can send delayed IOD 222 to divider 218 and to DCD circuit 230. Divider 218 can be an integer divider configured to divide an input signal, such as delayed IOD 222, by a predefined integer of 2. The output of divider 218 is the output clock signal CLK_out, which is a result of dividing the input clock signal CLK_in by a value that can be a combination of integer 102 and fraction 104. Divider 218 can operate as a duty cycle correction circuit to ensure the duty cycle of CLK_out is 50% to achieve a desired square waveform.

The DCD circuit 230 can be a part of a feedback loop that provides a feedback IOD signal 231 back to edge sampler 214. The feedback IOD signal 231 can be the delayed IOD 222, or a further delayed version of delayed IOD 222, depending on a DCD code 206 being provided by circuit 212 during a calibration process to calibrate DCD circuit 220 (described below). Edge sampler 214 can compare the IOD signal 231 with the input clock signal CLK_in to check whether edges of the IOD signal 231 and the input clock signal CLK_in are aligned during the calibration process described in the present disclosure.

As a result of using the dual DCD circuit topology having two DCD circuits 220, 230, jitter can be reduced while the output DCD circuit 220 can be calibrated by DCD circuit 230 for PVT variations. In the calibration process described in the present disclosure, the DCD circuit 230 can change the characteristics of the DCD circuit 220 such that the output of DCD circuit 220 is aligned with the rising (or falling edge, depending on a desired implementation and/or application) of the input clock signal CLK_in despite PVT variations.

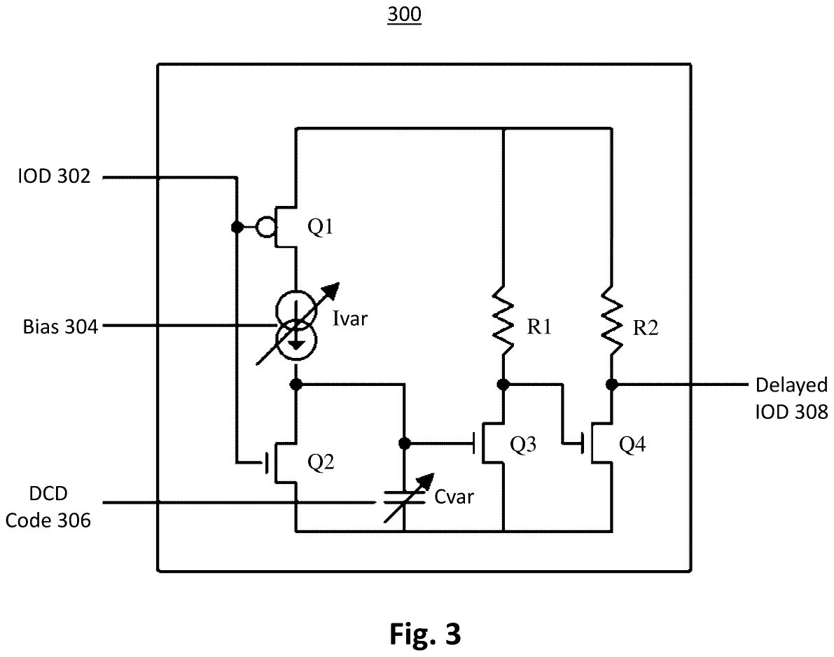

FIG. 3 shows an example implementation of a digital control delay (DCD) circuit in one embodiment. Descriptions of FIG. 3 can reference components shown in FIG. 1 and FIG. 2. A DCD circuit 300 being shown in FIG. 3 can be an example implementation of DCD circuit 220 and/or DCD circuit 230 described in the present disclosure. The implementation shown in FIG. 3 is one example implementation of a DCD circuit, and other implementations can also be used for implementing DCD circuit 220 and/or DCD circuit 230. DCD circuit 300 can receive an integer output divider result labeled as IOD 302, a bias 304, and a DCD code 306. DCD circuit 300 can apply a delay on IOD 302 to generate a delayed IOD 308.

When DCD circuit 300 is configured as an output DCD circuit, such as DCD circuit 220, IOD 302 is IOD 112, bias 304 can be bias 213, DCD code 306 is signal 217, and delayed IOD 308 is delayed IOD 222. When DCD circuit 300 is configured as a calibration DCD circuit, such as DCD circuit 230, IOD 302 is delayed IOD 222, bias 304 can be bias 213, DCD code 306 is DCD code 206, and delayed IOD 308 is feedback signal 231.

DCD code 306 can adjust or tune a variable capacitance Cvar to change the charge or discharge characteristics of the DCD circuit 300. Increasing the capacitance of Cvar can increase a delay being applied to IOD 302, and decreasing the capacitance of Cvar can decrease the delay being applied to IOD 302. Bias 304 can adjust or tune a variable current source Ivar to change the charge or discharge characteristics of the DCD circuit 300. The adjustment of Cvar and Ivar can be independent from one another. Other implementations to change the charge or discharge characteristics of DCD circuit 300 can include adjusting a variable resistance, selectively switching resistors in a resistor network, selectively switching capacitors in a capacitor network, or other implementations.

IOD 302 can be inputted to a complementary metal-oxide-semiconductor (CMOS) inverter formed by switching devices Q1, Q2. A resistive load R1 and a switching device Q3 can form an inverter, and a resistive load R2 and a switching device Q4 can form another inverter. Switching device Q1 can be a P-type metal-oxide-semiconductor (PMOS) device and switching devices Q2, Q3, Q4 can be an N-type metal-oxide-semiconductor (NMOS) device. The components in FIG. 3 forming the inverters in DCD circuit 300 is one example implementation. Other implementations, such as replacing Q3, Q4 with PMOS devices, can be used as well. The inverters in DCD circuit 300, along with tuning of Ivar and Cvar, can apply delays on IOD 302 to generate delayed IOD 308.

The tuning of variable capacitor Cvar can produce a delay that ranges from zero to one

period of the input clock signal CLK_in (e.g., full cycle delay), where this period is denoted as Tvco in the present disclosure. By way of example, if DCD code 306 is 8-bits, then DCD code 306 being 00000000 may indicate no delay (e.g., delay=zero, or minimum delay), and 11111111 may indicate a delay equal to 255/256 of the VCO output or CLK_in. When DCD circuit 300 is configured as the calibration DCD circuit 230, an extra least significant bit (LSB) can be added to the DCD code 306 to correspond to one VCO cycle, or one Tvco.

In one embodiment, when DCD circuit 300 is an output DCD circuit (e.g., DCD circuit 220), the current source Ivar and variable capacitor Cvar can be calibrated by another copy of DCD circuit 300 (e.g., calibration DCD circuit 230) periodically. In an aspect, as the PVT characteristics of the DCD circuit 300 changes, the maximum DCD code 306 (e.g., 11111111 for 8-bit DCD code) may no longer generate a delay of one Tvco. Also, the minimum DCD code 306 (e.g., 00000000 for 8-bit DCD code) may no longer generate a minimum delay (e.g., zero, or a known minimum delay) as the PVT characteristics of the DCD circuit 300 changes. Therefore, it is desirable to calibrate the output DCD circuit periodically to ensure that the DCD code 306 corresponds to the correct delay. In one embodiment, the calibration DCD circuit 230 can be activated periodically to calibrate the output DCD circuit 220, and can remain deactivated when calibration is not taking place.

In one embodiment, when DCD circuit 300 is configured as the calibration DCD circuit 230, DCD circuit 300 can operate in one of two delay modes: a 0-delay mode or a 1-delay mode. When DCD code 206 is the minimum DCD code, DCD circuit 300 can operate in the 0-delay mode. When DCD code 206 is the maximum DCD code, DCD circuit 300 can operate in the 1-delay mode. Referring to FIG. 2, when calibration DCD circuit 230 is in the 0-delay mode, calibration DCD circuit 230 applies a minimum delay on the delayed IOD 222 to generate feedback IOD 231. Circuit 212 can control the operation of calibration DCD circuit 230 under the 0-delay mode or the 1-delay mode under different conditions or stages during the calibration process described in the present disclosure.

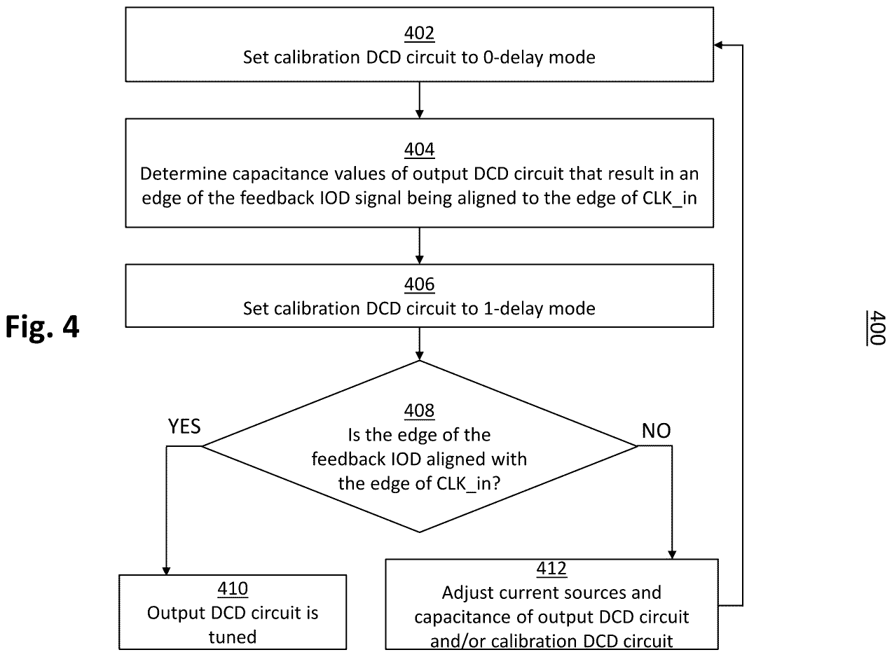

FIG. 4 is a diagram showing an example calibration process 400 in one embodiment. Descriptions of FIG. 4 can reference components shown in FIG. 1 to FIG. 3. Process 400 can be performed by one or more components in circuit 120. Process 400 can include a zero position search stage and a check alignment stage. The zero position search stage can include block 402, and 404, and the check alignment stage can include blocks 406, 408, 412.

Process 400 can begin at block 402. At block 402, circuit 212 can set DCD code 206 to a minimum DCD code in order to set calibration DCD circuit 230 to 0-delay mode. As a result of setting calibration DCD circuit 230 to 0-delay mode, calibration DCD circuit 230 will apply its minimum delay, which may be zero or greater than zero, on delayed IOD 222 such that feedback IOD 231 is equivalent to delayed IOD 222. In one embodiment, the minimum delay applied by calibration DCD circuit 230 can be the delay that is set when Cvar in calibration DCD circuit 230 is set to zero (e.g., no capacitors are switched into the circuit). When Cvar in calibration DCD circuit 230 is zero, other components such as Ivar can contribute to the minimum delay being applied in the zero delay mode.

Process 400 can proceed from block 402 to block 404. At block 404, circuit 120 can determine capacitance values of output DCD circuit 220 that will cause an edge of the feedback IOD signal 231 to align with an edge of CLK_in. The edge being aligned can be either the rising edge or the falling edge. By way of example, edge sampler 214 can determine whether the rising edge of the feedback IOD signal 231 aligns with the rising edge of CLK_in. If the rising edge of the feedback IOD signal 231 aligns with the rising edge of CLK_in, then edge sampler 214 can generate edge signal 215 to indicate the alignment and process 400 can proceed to block 406. In examples where falling edges are being checked for alignment, edge sampler 214 can determine whether the falling edge of the feedback IOD signal 231 aligns with the falling edge of CLK_in.

If the rising edge (or falling edge) of the feedback IOD signal 231 does not align with the rising edge (or falling edge) of CLK_in, then edge sampler 214 can generate edge signal 215 to indicate the misalignment or lack of alignment and circuit 212 can adjust the DCD code 206 to tune or adjust the capacitance of calibration DCD circuit 230 until edge sampler 214 determines that the rising edge (or falling edge) of the feedback IOD signal 231 aligns with the rising edge (or falling edge) of CLK_in. If the rising edge (or falling edge) of the feedback IOD signal 231 is later than the rising edge (or falling edge) of CLK_in, then circuit 212 can control phase selector 216 to tune Cvar of output DCD circuit 220, while calibration DCD circuit 230 remains in 0-delay mode, to reduce the delay being applied by output DCD circuit 220. If the rising edge (or falling edge) of the feedback IOD signal 231 is earlier than the rising edge (or falling edge) of CLK_in, then circuit 212 can tune Cvar of output DCD circuit 220 to increase the delay being applied by output DCD circuit 220. When the capacitance of output DCD circuit 220 is tuned to the value where the rising edge (or falling edge) of the feedback IOD signal 231 aligns with the rising edge (or falling edge) of CLK_in, circuit 212 can log the capacitance of the output DCD circuit 220. In one embodiment, circuit 212 can write the logged capacitance values in registers that may reside in circuit 212. Once the capacitance values are determined and logged, process 400 can proceed to block 406. Note that since calibration DCD circuit 230 remains in 0-delay mode while output DCD circuit 220 is being tuned, the tuning of capacitance of output DCD circuit 220 can allow system 100 to identify a capacitance of output DCD circuit 220 that can result in delayed IOD signal 222 being aligned with CLK_in.

At block 406, circuit 212 can set DCD code 206 to a maximum DCD code in order to set calibration DCD circuit 230 to 1-delay mode. As a result of setting calibration DCD circuit 230 to 1-delay mode, calibration DCD circuit 230 will apply a delay of one Tvco on delayed IOD 222 to generate feedback IOD 231. In one embodiment, the delay applied by calibration DCD circuit 230 under the 1-delay mode can be the delay that is set when Cvar in calibration DCD circuit 230 is maximized (e.g., all capacitors are switched into the circuit).

Process 400 can proceed from block 406 to block 408. At block 408, edge sampler 214 can determine whether the rising edge (or falling edge) of the feedback IOD signal 231 is aligned to the rising edge (or falling edge) of CLK_in If the rising edge (or falling edge) of the feedback IOD signal 231 does not align with the rising edge (or falling edge) of CLK_in at the decision block 408 (408: NO), then process 400 can proceed to block 412. At block 412, edge sampler 214 can generate edge signal 215 to indicate the misalignment or lack of alignment and circuit 212 can generate bias 213 to adjust or tune the current source of calibration DCD circuit 230. If the rising edge (or falling edge) of the feedback IOD signal 231 is later than the rising edge (or falling edge) of CLK_in, then circuit 212 can generate bias 213 to tune Ivar of DCD circuit 230 to reduce the delay being applied by calibration DCD circuit 230. If the rising edge (or falling edge) of the feedback IOD signal 231 is earlier than the rising edge (or falling edge) of CLK_in, then circuit 212 can generate bias 213 to tune Ivar of DCD circuit 230 to increase the delay being applied by calibration DCD circuit 230. When the rising edge (or falling edge) of the feedback IOD signal 231 aligns with the rising edge (or falling edge) of CLK_in, the value of bias 213 can be logged, such as being written to registers, by circuit 212. Circuit 212 can set the output DCD circuit 220 to operate with the Cvar and Ivar tuned in blocks 404, 412 until the next calibration.

If the rising edge (or falling edge) of the feedback IOD signal 231 aligns with the rising edge (or falling edge) of CLK_in at the decision block 408 (408: YES), then the output DCD circuit 220 is tuned and process 400 can proceed to end at block 410. The alignment in block 408 can indicate that the difference between the outputs of the output DCD circuit 220 and the calibration DCD circuit 230 in the 1-delay mode is equal to one period of CLK_in, or one Tvco. Note that process 400 can loop back from block 412 to block 402 to set the calibration DCD circuit 230 to 0-delay mode such that the capacitance of output DCD circuit 220 can be tuned again to align the edges of feedback IOD 231 and CLK_in. Note that the capacitance of output circuit 220 may change in response to changes in its current source. Therefore, process 400 can loop back to block 402 to repeat the entire process 400 until edges of feedback IOD 231 and CLK_in are aligned under both 0-delay and 1-delay modes. When the edges of feedback IOD 231 and CLK_in are aligned under both 0-delay and 1-delay modes, the DCD code and bias that were used and logged by circuit 212 for tuning the capacitance and current source of calibration circuit 230 can be applied to output circuit 220 such that output DCD circuit 220 is calibrated. The calibration can cause output DCD circuit 220 to apply delay on subsequent IOD signals that is based on its Cvar and Ivar set by the DCD code and bias determined from process 400. At block 410, the difference between the outputs of the output DCD circuit 220 and the calibration DCD circuit 230 in both the 0-delay mode and 1-delay mode are equal, which indicates output DCD circuit 220 is calibrated in the range from zero delay to one Tvco delay. The process 400 can be performed periodically to calibrate output DCD circuit 220 to account for the PVT variations.

In one embodiment, at block 404, circuit 212 can set the capacitance of the output DCD circuit 220 (via phase selector 216) and calibration DCD circuit 230 (via DCD code 206) to be the same capacitance value. After setting to the same capacitive value, circuit 212 can determine the phase difference between the edges (rising or falling edge) of feedback IOD signal 231 and CLK_in. The phase difference identify and find the zero z0 between 0-0.5 and find the next one-rising location at z0+0.5

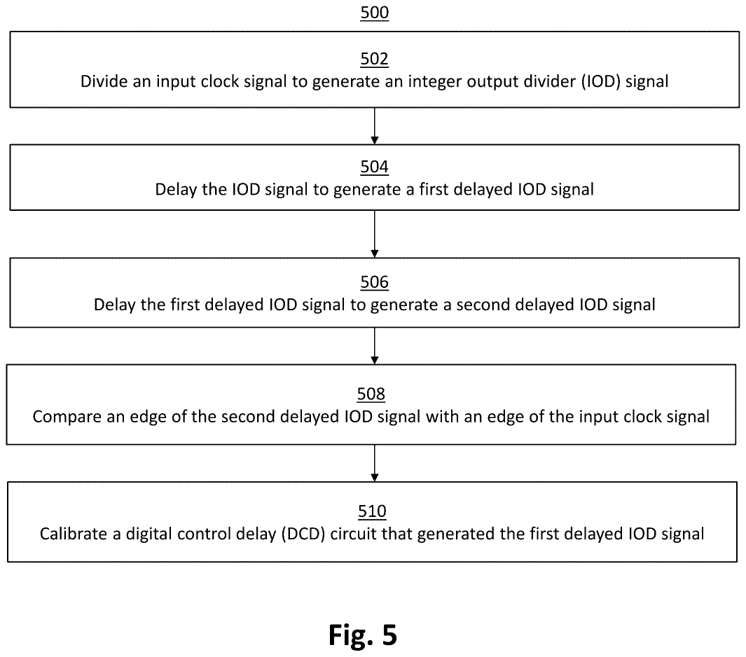

FIG. 5 is a flowchart of an example process that can implement fractional divider calibration with dual digital control delay circuits in one embodiment. Descriptions of FIG. 5 may reference components shown in FIGS. 1-4. The process 500 can include one or more operations, actions, or functions as illustrated by one or more of blocks 502, 504, 506, 508, and 510. Although illustrated as discrete blocks, various blocks can be divided into additional blocks, combined into fewer blocks, eliminated, performed in different order, or performed in parallel, depending on the desired implementation.

Process 500 can be performed by a circuit described herein, such as circuit 120 or one or more components in circuit 120 in system 100 described in the present disclosure. Process 500 can begin at block 502. At block 502, a circuit can divide an input clock signal to generate an integer output divider (IOD) signal.

Process 500 can proceed from block 502 to block 504. In block 504, the circuit can delay the IOD signal to generate a first delayed IOD signal.

Process 500 can proceed from block 504 to block 506. In block 506, the circuit can delay the first delayed IOD signal to generate a second delayed IOD signal.

Process 500 can proceed from block 506 to block 508. In block 508, the circuit can compare an edge of the second delayed IOD signal with an edge of the input clock signal. In one embodiment, the edge is one of a rising edge and a falling edge.

Process 500 can proceed from block 508 to block 510. In block 510, the circuit can calibrate a digital control delay (DCD) circuit that generated the first delayed IOD signal. The calibration can be based on a result of the comparison between the edge of the second delayed IOD signal with the edge of the input clock signal. In one embodiment, the circuit can calibrate the first delayed IOD signal by tuning a capacitance of the DCD circuit and supplying a bias to tune a current source of the DCD circuit. In one embodiment, the circuit can calibrate the DCD circuit periodically. In one embodiment, the calibration in block 510 can be applicable to at least one of the first DCD circuit and a second DCD circuit that generated the second delayed IOD signal.

In one embodiment, the DCD circuit can be a first DCD circuit and the second delayed IOD signal is equivalent to the first delayed IOD signal when a second DCD circuit operates under a zero-delay mode, where the second DCD circuit can be generated the second delayed IOD signal. In one embodiment, the second IOD signal can lag the first delayed IOD signal by a full cycle when the second DCD circuit operates under a one-delay mode.

In one embodiment, the DCD circuit can be a first DCD circuit and a second DCD circuit generates the second delayed IOD signal. The circuit can calibrate the first DCD circuit and/or the second DCD circuit by setting the second DCD circuit to operate in a zero-delay mode to apply a minimum delay on the first delayed IOD signal such that the second delayed IOD signal is equivalent to the first delayed IOD signal, tuning a capacitance of the first DCD circuit and/or the second DCD circuit, setting the second DCD circuit to operate in a one-delay mode to apply a full cycle delay on the first delayed IOD signal, and supplying a bias to tune a current source of the first DCD circuit and/or the second DCD circuit.

In one embodiment, when the second DCD circuit operates in the zero-delay mode, the circuit can tune the capacitance of the first DCD circuit when the edge of the second delayed IOD signal misaligns with the edge of the input clock signal and stop tuning the capacitance of the first DCD circuit when the edge of the second delayed IOD signal aligns with the edge of the input clock signal. When the second DCD circuit operates in the one-delay mode, the circuit can supply the bias to tune a current source of the first DCD circuit and stop the supply of the bias to tune the current source of the first DCD circuit.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be implemented substantially concurrently, or the blocks may sometimes be implemented in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

### EXAMPLES

Example 1: A semiconductor device comprising: a first digital control delay (DCD) circuit configured to delay an integer output divider (IOD) signal to generate a first delayed IOD signal; a second DCD circuit configured to delay the first delayed IOD signal to generate a second delayed IOD signal; an edge sampler configured to sample an edge of the second delayed IOD signal; and a controller configured to calibrate the first DCD circuit based on the edge sampled from the second delayed IOD signal.

Example 2: The semiconductor device of Example 1, wherein: the second delayed IOD signal is equivalent to the first delayed IOD signal when the second DCD circuit operates under a zero-delay mode; and the second DCD circuit delays the first delayed IOD signal by a full cycle under a one-delay mode.

Example 3: The semiconductor device of Example 1 or Example 2, wherein the edge is one of a rising edge and a falling edge of the second delayed IOD signal.

Example 4: The semiconductor device of any one of Examples 1 to 3, wherein to calibrate the first DCD circuit, the controller is configured to: tune a capacitance of the second DCD circuit; and supply a bias to tune a current source of the second DCD circuit.

Example 5: The semiconductor device of any one of Examples 1 to 4, wherein the controller is configured to calibrate the first DCD circuit periodically.

Example 6: The semiconductor device of any one of Examples 1 to 5, wherein to calibrate the first DCD circuit the controller is configured to: set the second DCD circuit to operate in a zero-delay mode to apply a minimum delay on the first delayed IOD signal such that the second delayed IOD signal is equivalent to the first delayed IOD signal; tune a capacitance of the second DCD circuit; set the second DCD circuit to operate in a one-delay mode to apply a full cycle delay on the first delayed IOD signal; and supply a bias to tune a current source of the second DCD circuit.

Example 7: A system comprising: a divider configured to divide an input clock signal to generate an integer output divider (IOD) signal; a circuit comprising: a first digital control delay (DCD) circuit configured to delay the IOD signal to generate a first delayed IOD signal; a second DCD circuit configured to delay the first delayed IOD signal to generate a second delayed IOD signal; an edge sampler configured to compare an edge of the second delayed IOD signal with an edge of the input clock signal; and a controller configured to calibrate the first DCD circuit based on a result of the comparison between the edge of the second delayed IOD signal with the edge of the input clock signal.

Example 8: The system of Example 7, wherein: the second delayed IOD signal is equivalent to the first delayed IOD signal when the second DCD circuit operates under a zero-delay mode; and the second DCD circuit delays the first delayed IOD signal by a full cycle under a one-delay mode.

Example 9: The system of Example 7 or Example 8, wherein the edge is one of a rising edge and a falling edge.

Example 10: The system of any one of Examples 7 to 9, wherein to calibrate the first DCD circuit, the controller is configured to: tune a capacitance of the second DCD circuit; and supply a bias to tune a current source of the second DCD circuit.

Example 11: The system of any one of Examples 7 to 10, wherein the controller is configured to calibrate the first DCD circuit periodically.

Example 12: The system of any one of Examples 7 to 11, wherein to calibrate the first DCD circuit, the controller is configured to: set the second DCD circuit to operate in a zero-delay mode to apply a minimum delay on the first delayed IOD signal such that the second delayed IOD signal is equivalent to the first delayed IOD signal; tune a capacitance of the second DCD circuit; set the second DCD circuit to operate in a one-delay mode to apply a full cycle delay on the first delayed IOD signal; and supply a bias to tune a current source of the second DCD circuit.

Example 13: The system of any one of Examples 7 to 12, wherein: when the second DCD circuit operates in the zero-delay mode, the controller is configured to: receive a signal indicating a result of the comparison between the edge of the second delayed IOD signal and the edge of the input clock signal; in response to the signal indicating the edge of the second delayed IOD signal misaligns with the edge of the input clock signal, tune the capacitance of the second DCD circuit; and in response to the signal indicating the edge of the second delayed IOD signal aligns with the edge of the input clock signal, stop tuning the capacitance of the second DCD circuit; when the second DCD circuit operates in the one-delay mode, the controller is configured to: receive the signal indicating a result of the comparison between the edge of the second delayed IOD signal and the edge of the input clock signal; in response to the signal indicating the edge of the second delayed IOD signal misaligns with the edge of the input clock signal, supply the bias to tune the current source of the second DCD circuit; and in response to the signal indicating the edge of the second delayed IOD signal aligns with the edge of the input clock signal, stop supplying the bias to tune the current source of the second DCD circuit.

Example 14: A method comprising: dividing an input clock signal to generate an integer output divider (IOD) signal; delaying the IOD signal to generate a first delayed IOD signal; delaying the first delayed IOD signal to generate a second delayed IOD signal; comparing an edge of the second delayed IOD signal with an edge of the input clock signal; and calibrating a digital control delay (DCD) circuit that generated the first delayed IOD signal, wherein the calibration is based on a result of the comparison between the edge of the second delayed IOD signal with the edge of the input clock signal.

Example 15: The method of Example 14, wherein: the DCD circuit is a first DCD circuit; the second delayed IOD signal is equivalent to the first delayed IOD signal when a second DCD circuit operates under a zero-delay mode, wherein the second DCD circuit generated the second delayed IOD signal; and the second IOD signal lags the first delayed IOD signal by a full cycle when the second DCD circuit operates under a one-delay mode.

Example 16: The method of Example 14 or Example 15, wherein the edge is one of a rising edge and a falling edge.

Example 17: The method of any one of Examples 14 to 16, wherein calibrating the first delayed IOD signal comprises: tuning a capacitance of another DCD circuit that generated the second delayed IOD signal; and supplying a bias to tune a current source of said another DCD circuit.

Example 18: The method of any one of Examples 14 to 17, wherein calibrating the DCD circuit is performed periodically.

Example 19: The method of any one of Examples 14 to 18, wherein the DCD circuit is a first DCD circuit and a second DCD circuit generates the second delayed IOD signal, and calibrating the DCD circuit comprises: setting the second DCD circuit to operate in a zero-delay mode to apply a minimum delay on the first delayed IOD signal such that the second delayed IOD signal is equivalent to the first delayed IOD signal; tuning a capacitance of the second DCD circuit; setting the second DCD circuit to operate in a one-delay mode to apply a full cycle delay on the first delayed IOD signal; and supplying a bias to tune a current source of the second DCD circuit.

Example 20: The method of any one of Examples 14 to 19, further comprising: when the second DCD circuit operates in the zero-delay mode: tuning the capacitance of the second DCD circuit when the edge of the second delayed IOD signal misaligns with the edge of the input clock signal; and stopping the tuning the capacitance of the second DCD circuit when the edge of the second delayed IOD signal aligns with the edge of the input clock signal; when the second DCD circuit operates in the one-delay mode: supplying the bias to tune a current source of the second DCD circuit; and stopping the supply of the bias to tune the current source of the second DCD circuit.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present disclosure have been presented for purposes of illustration and description but are not intended to be exhaustive or limited to the present disclosure in the forms disclosed. Many modifications and variations will be apparent to those of ordinary skill in the art without departing from the scope and spirit of the present disclosure. The embodiments were chosen and described in order to best explain the principles of the present disclosure and the practical application, and to enable others of ordinary skill in the art to understand the present disclosure for various embodiments with various modifications as are suited to the particular use contemplated.

What is claimed is:

1. A semiconductor device comprising:
a first digital control delay (DCD) circuit configured to delay an integer output divider (IOD) signal to generate a first delayed IOD signal;
a second DCD circuit configured to delay the first delayed IOD signal to generate a second delayed IOD signal;
an edge sampler configured to sample an edge of the second delayed IOD signal; and
a controller configured to calibrate the first DCD circuit based on the edge sampled from the second delayed IOD signal.

2. The semiconductor device of claim 1, wherein:
the second delayed IOD signal is equivalent to the first delayed IOD signal when the second DCD circuit operates under a zero-delay mode; and
the second DCD circuit delays the first delayed IOD signal by a full cycle under a one-delay mode.

3. The semiconductor device of claim 1, wherein the edge is one of a rising edge and a falling edge of the second delayed IOD signal.

4. The semiconductor device of claim 1, wherein to calibrate the first DCD circuit, the controller is configured to:
tune a capacitance of the second DCD circuit; and
supply a bias to tune a current source of the second DCD circuit.

5. The semiconductor device of claim 1, wherein the controller is configured to calibrate the first DCD circuit periodically.

6. The semiconductor device of claim 1, wherein to calibrate the first DCD circuit the controller is configured to:
set the second DCD circuit to operate in a zero-delay mode to apply a minimum delay on the first delayed IOD signal such that the second delayed IOD signal is equivalent to the first delayed IOD signal;
tune a capacitance of the second DCD circuit;
set the second DCD circuit to operate in a one-delay mode to apply a full cycle delay on the first delayed IOD signal; and
supply a bias to tune a current source of the second DCD circuit.

7. A system comprising:
a divider configured to divide an input clock signal to generate an integer output divider (IOD) signal;
a circuit comprising:
a first digital control delay (DCD) circuit configured to delay the IOD signal to generate a first delayed IOD signal;
a second DCD circuit configured to delay the first delayed IOD signal to generate a second delayed IOD signal;
an edge sampler configured to compare an edge of the second delayed IOD signal with an edge of the input clock signal; and
a controller configured to calibrate the first DCD circuit based on a result of the comparison between the edge of the second delayed IOD signal with the edge of the input clock signal.

8. The system of claim 7, wherein:
the second delayed IOD signal is equivalent to the first delayed IOD signal when the second DCD circuit operates under a zero-delay mode; and
the second DCD circuit delays the first delayed IOD signal by a full cycle under a one-delay mode.

9. The system of claim 7, wherein the edge is one of a rising edge and a falling edge.

10. The system of claim 7, wherein to calibrate the first DCD circuit, the controller is configured to:
tune a capacitance of the second DCD circuit; and
supply a bias to tune a current source of the second DCD circuit.

11. The system of claim 7, wherein the controller is configured to calibrate the first DCD circuit periodically.

12. The system of claim 7, wherein to calibrate the first DCD circuit, the controller is configured to:
set the second DCD circuit to operate in a zero-delay mode to apply a minimum delay on the first delayed IOD signal such that the second delayed IOD signal is equivalent to the first delayed IOD signal;
tune a capacitance of the second DCD circuit;
set the second DCD circuit to operate in a one-delay mode to apply a full cycle delay on the first delayed IOD signal; and
supply a bias to tune a current source of the second DCD circuit.

13. The system of claim 12, wherein:
when the second DCD circuit operates in the zero-delay mode, the controller is configured to:
receive a signal indicating a result of the comparison between the edge of the second delayed IOD signal and the edge of the input clock signal;
in response to the signal indicating the edge of the second delayed IOD signal misaligns with the edge of the input clock signal, tune the capacitance of the second DCD circuit; and
in response to the signal indicating the edge of the second delayed IOD signal aligns with the edge of the input clock signal, stop tuning the capacitance of the second DCD circuit; and
when the second DCD circuit operates in the one-delay mode, the controller is configured to:
receive the signal indicating a result of the comparison between the edge of the second delayed IOD signal and the edge of the input clock signal;
in response to the signal indicating the edge of the second delayed IOD signal misaligns with the edge of the input clock signal, supply the bias to tune the current source of the second DCD circuit; and
in response to the signal indicating the edge of the second delayed IOD signal aligns with the edge of the input clock signal, stop supplying the bias to tune the current source of the second DCD circuit.

14. A method comprising:
dividing an input clock signal to generate an integer output divider (IOD) signal;
delaying the IOD signal to generate a first delayed IOD signal;
delaying the first delayed IOD signal to generate a second delayed IOD signal;
comparing an edge of the second delayed IOD signal with an edge of the input clock signal; and
calibrating a digital control delay (DCD) circuit that generated the first delayed IOD signal, wherein the calibration is based on a result of the comparison between the edge of the second delayed IOD signal with the edge of the input clock signal.

15. The method of claim 14, wherein:
the DCD circuit is a first DCD circuit;
the second delayed IOD signal is equivalent to the first delayed IOD signal when a second DCD circuit operates under a zero-delay mode, wherein the second DCD circuit generated the second delayed IOD signal; and
the second IOD signal lags the first delayed IOD signal by a full cycle when the second DCD circuit operates under a one-delay mode.

16. The method of claim 14, wherein the edge is one of a rising edge and a falling edge.

17. The method of claim 14, wherein calibrating the first delayed IOD signal comprises:
tuning a capacitance of another DCD circuit that generated the second delayed IOD signal; and
supplying a bias to tune a current source of said another DCD circuit.

18. The method of claim 14, wherein calibrating the DCD circuit is performed periodically.

19. The method of claim 14, wherein the DCD circuit is a first DCD circuit and a second DCD circuit generates the second delayed IOD signal, and calibrating the DCD circuit comprises:
setting the second DCD circuit to operate in a zero-delay mode to apply a minimum delay on the first delayed IOD signal such that the second delayed IOD signal is equivalent to the first delayed IOD signal;
tuning a capacitance of the second DCD circuit;
setting the second DCD circuit to operate in a one-delay mode to apply a full cycle delay on the first delayed IOD signal; and
supplying a bias to tune a current source of the second DCD circuit.

20. The method of claim 19, further comprising:
when the second DCD circuit operates in the zero-delay mode:
tuning the capacitance of the second DCD circuit when the edge of the second delayed IOD signal misaligns with the edge of the input clock signal; and
stopping the tuning the capacitance of the second DCD circuit when the edge of the second delayed IOD signal aligns with the edge of the input clock signal; and
when the second DCD circuit operates in the one-delay mode:
supplying the bias to tune a current source of the second DCD circuit; and
stopping the supply of the bias to tune the current source of the second DCD circuit.
